(19) United States
(12) Patent Application Publication
(10) Pub. No.: US 2013/0126938 A1
(43) Pub. Date: May 23, 2013

(54) Optoelectronic Semiconductor Element and Associated Method of Production by Direct Welding of Glass Housing Components by Means of Ultra Short Pulsed Laser without Glass Solder

(71) Applicants: Angela Eberhardt, Augsburg (DE); Joachim Wirth-Schön, Gunzburg (DE)

(72) Inventors: Angela Eberhardt, Augsburg (DE); Joachim Wirth-Schön, Gunzburg (DE)

(21) Appl. No.: 13/812,809

(22) PCT Filed: Jul. 15, 2011
(86) PCT No.: PCT/EP11/62145

§ 371 Date: Jan. 28, 2013

(30) Foreign Application Priority Data
Jul. 28, 2010 (DE) 10 2010 038 554.9

(51) Int. Cl. H01L 33/48

(52) U.S. Cl. CPC H01L 33/483
USPC 257/99; 438/26

(57) ABSTRACT

An optoelectronic semiconductor element having a light source, a housing and electrical terminals, wherein the optoelectronic semiconductor element comprises components, which are produced from glass, and wherein at least two components touch at boundary surfaces adjusted to one another and are welded to one another directly there.

### TECHNICAL FIELD

The invention is based on an optoelectronic semiconductor element as claimed in the preamble of claim 1. It also describes an associated method of production.

### PRIOR ART

DE-A 10118630 and DE-A 10159544 disclose LEDs with glass components.

JP 2001-266800 describes a method for hot laser welding of two glass molded parts. U.S. Pat. No. 6,936,963 already discloses a method for encapsulating an element on the basis of an organic semiconductor, consisting of a transparent substrate, an electrode attached thereto, luminescent layers of various colors and a counter electrode. The semiconductor element is encapsulated in an air-tight manner by means of a housing, said housing being connected to the substrate by way of an adhesive. A further alternative is the use of an IR diode laser or Co2 laser in addition to the adhesive.

### REPRESENTATION OF THE INVENTION

An object of the present invention is to create a durable and hermetic encapsulation of sensitive components in glass in an optoelectronic semiconductor element as claimed in the preamble of claim 1.

This object is achieved by the characterizing features of claim 1.

Particularly advantageous embodiments are found in the dependent claims.

The present invention solves the problem of creating a temperature and weather-resistant encapsulation for optoelectronic semiconductor elements.

A hermetically sealed encapsulation of components such as organic layers in OLEDs or other sensitive components in LEDs is currently realized by means of glass solder or organic adhesives between the glass parts to be connected.

Organic LEDs (OLED), in particular displays made from organic LEDs, consists of a package of organic layers (the actual OLED) and metal layers for contacting (electrodes), which are disposed between two thin glass plates (e.g. 0.5 to 1.0 mm thick). These form the base (substrate) and the cover of a housing. The housing may furthermore possibly also comprise side walls. Without encapsulation, these layers would be corroded by oxygen and vapor thereby resulting in failure of the OLED. An encapsulation for the OLED was developed, which durably connects the remaining housing parts with the substrate and surrounds the OLED in a gas-tight manner, thereby protecting the same from oxygen and moisture. During sealing, the OLED should not be damaged by thermal overload.

A method was developed to connect the substrate and remaining housing parts made of glass, between which the OLED is disposed, in a stable manner without the aid of glass solder, and to surround the OLED in a gas-tight manner.

LEDs were previously produced in most instances by including organic components, this applies in particular to board, lens or also conversion elements of the LED. Moreover, an organic adhesive is often used as the adhesive, in order for instance to attach a cover made of glass or to glue a conversion element to a chip.

Organic components of this type have a poor thermal conductivity and a low UV resistance, particularly in terms of the resistance to radiation in the range below 420 nm. In addition, they are temperature-sensitive. This results in a low efficiency, because the LED discolors or is operated at an excessively high temperature.

One problem in particular is that no durably tight seal against moisture is achieved with adhesives. Conversely with encapsulation by means of glass solder, process temperatures occur which have a negative effect on the encapsulated component.

In accordance with the invention, a durable and hermetically tight connection between two components made of glass is achieved by a direct welding of the glass molded parts. The use of short pulsed lasers now make welding possible. By contrast with longer laser pulses in other systems, extremely high stress does not develop in the glass molded parts during the process. This would previously have resulted in the failure of glass molded parts on account of crack formation.

With the welding with short pulsed lasers, in particular with ultra short pulsed lasers with pulse widths in the femto and picosecond range, only the boundary layers of the glass molded parts disposed one above the other are intentionally melted through the glass molded part. A temporal and locally greatly restricted heated zone is thus achieved.

The direct laser welding of the glass molded parts achieves a durable and hermetic connection between the two glass molded parts. The laser welding process can take place at room temperature or also at an increased temperature.

No additional materials or heating steps are thus necessary. A heating process is also omitted. The new method allows glass molded parts to be reliably connected, which, on account of the high stresses occurring in the process, could not be durably mechanically connected to one another by conventional, macroscopic direct welding.

An optoelectronic semiconductor component produced in this way is in particular an OLED.

Essential features of the invention in the form of a numbered list are:

1. Optoelectronic semiconductor element having a light source, a housing and electrical terminals, wherein the optoelectronic semiconductor element has components, which are made of glass, characterized in that at least two components touch one another at boundary surfaces adjusted to one another and are directly welded to one another there.

2. Optoelectronic semiconductor element as claimed in claim 1, characterized in that the components are integral parts of the housing.

3. Optoelectronic semiconductor element as claimed in claim 1, characterized in that the semiconductor element is an LED or OLED.

4. Method for producing an optoelectronic semiconductor element as claimed in claim 1, characterized in that the welding takes place at room temperature by means of ultra short laser pulses.

5. Method as claimed in claim 4, characterized in that the laser pulses are between 100 fs and 500 ps long, in particular between 500 fs and 100 ps.

6. Method as claimed in claim 4, characterized in that the repetition rate of the laser pulses amounts to between 10 kHz and 2 MHz.

7. Method as claimed in claim 4, characterized in that a femto or picosecond laser is used as a laser.

### BRIEF DESCRIPTION OF THE DRAWINGS

The invention is to be explained in more detail below with the aid of several exemplary embodiments. The figures show:

FIG. 1 an LED with a glass cover in the cross-section;

FIG. 2 an OLED in the cross-section;

FIG. 3 a schematic diagram of a welded seam viewed from above;

FIG. 4 a top view onto an OLED;

FIG. 5 a side view of an OLED.

### PREFERRED EMBODIMENT OF THE INVENTION

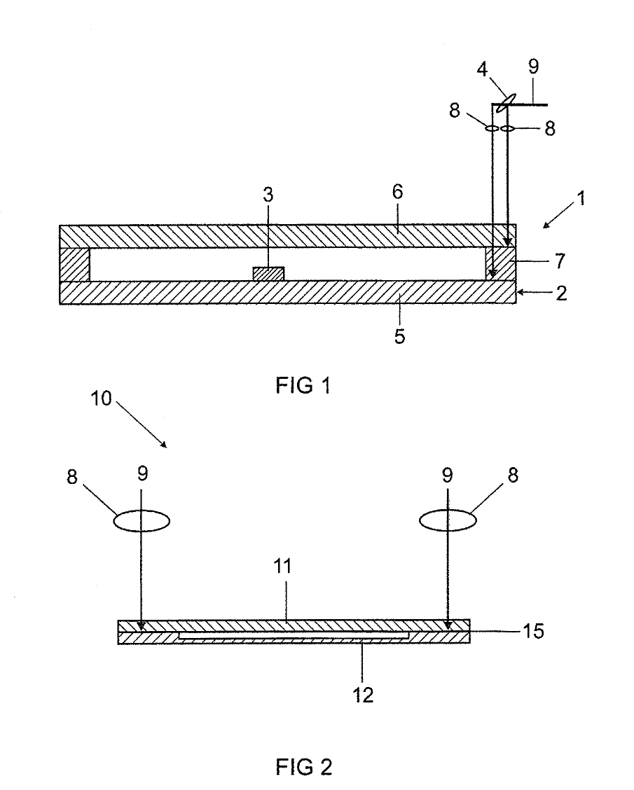

FIG. 1 shows a schematic representation of a schematic diagram of an LED 1, in which a laser direct welding of glass molded parts is applied. The LED comprises a housing 2, in which a chip 3 is disposed. In this case the housing 2 of the LED is assembled by means of direct laser welding. The glass molded parts are an approximately rectangular base part 5 and a similarly embodied cover part 6. These are in contact with one another by way of side walls 7.

The beam 9 of an ultrasound pulse laser, for instance a picosecond laser, is focused such that its focus is adjusted on the one hand to the boundary between the side wall 7 and the ceiling part 6 and on the other hand to the boundary between the side wall 7 and the base part 5. This boundary can be reliably welded in each instance with the ultra short laser pulses of the beam 9. The different focus can be achieved for instance by means of beam splitter 4 and lens 8.

FIG. 2 shows a schematic representation of an OLED 10, which is in principle structured in a similar fashion to the LED from FIG. 1. The cover 11 is a glass substrate here, to which the OLED layers and the electrodes are attached (not shown). The base part 12 is embodied in the manner of a tray for instance. Separate side walls are omitted.

The beam 9 of an ultra short pulsed laser, for instance a picosecond laser, is focused by means of lens 8 such that its focus lies on the boundary 15 between the ceiling part 11 and the base part 12. This boundary 15 can be reliably sealed by glass welding with the ultra short laser pulses.

The melted area of the boundary region 15 between base 12 and cover 11 can be simultaneously sealed at several points using a beam splitter.

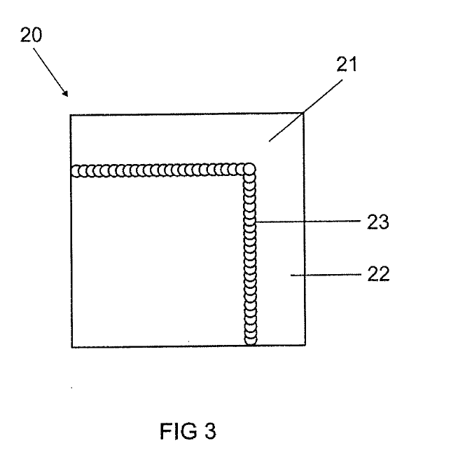

FIG. 3 shows a schematic of a welded glass connection system 20. Both the first component 21 and also the second component 22 is a plate made of glass. Both parts are welded to one another at room temperature by means of ultra short laser pulses (23). The method of direct glass welding by means of laser is particularly suited to soft glasses, since only low stresses occur here in the process. Hard glass or quartz glass can however also be connected to one another or to similar or especially also to soft glasses.

Instead of an LED, an OLED can also be used as an optoelectronic semiconductor element. The above considerations are at least just as critical. The hermetic sealing of OLEDS is one of the great challenges.

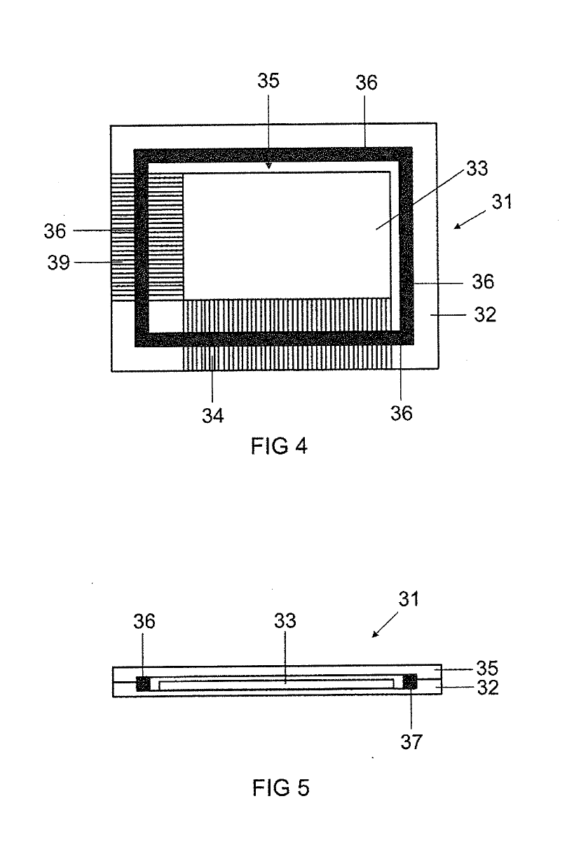

FIG. 4 shows a top view of a typical OLED. The side view is shown in FIG. 5. The OLED 31 consists of a substrate 32, to which an OLED array comprising pixels 33 is attached. This consists in a known manner of electrodes 34, electroluminescent organic layers, which are attached in layers, and counter electrodes 39. The circuit path terminals leading outwards are in each instance visible from the electrodes 34 and counter electrodes 39. The sealing of these terminals can if necessary also be effected by ultra short laser pulses.

The housing is realized as a cover 35 for instance by a transparent flat glass in the visible and near IR, wherein this comprises a lowered side wall 36. A similar side wall 37 shows the base part 32. The side walls 36 and 37 form an opposite boundary surface, which are welded to one another by means of ultra short laser pulses.

The method of production proceeds for instance such that a flat glass, for instance the sodalime display glass made by Merck, is used as a substrate and cover.

A typical seam includes a boundary zone with a thickness of 5 to 50 μm, which is produced at room temperature by the ultrasound laser by means of rapid pulses. The pulse lengths move during these pulses in the picosecond range at repetition rates of up to several hundred kilohertz.

1. An optoelectronic semiconductor element having a light source, a housing and electrical terminals, wherein the optoelectronic semiconductor element comprises components, which are produced from glass, and wherein at least two components touch at boundary surfaces adjusted to one another and are welded to one another directly there.

2. The optoelectronic semiconductor element as claimed in claim 1, wherein the components are integral parts of the housing.

3. The optoelectronic semiconductor element as claimed in claim 1, wherein the semiconductor component is an LED or OLED.

4. A method for manufacturing an optoelectronic semiconductor element as claimed in claim 1, wherein the welding takes place at room temperature by ultra short laser pulses.

5. The method as claimed in claim 4, wherein the laser pulses are between 100 fs and 500 ps long.

6. The method as claimed in claim 4, wherein the repetition rate of the laser pulse is between 10 kHz and 2 MHz.

7. The method as claimed in claim 4, wherein a femto or picosecond laser is used as a laser.

8. The method as claimed in claim 4, wherein the laser pulses are between 500 fs and 100 ps.
